(19) United States
(12) Patent Application Publication
(10) Pub. No.: US 2024/0021750 A1
(43) Pub. Date: Jan. 18, 2024

(54) EPITAXIAL PROCESSING OF SINGLE-CRYSTALLINE FILMS ON AMORPHOUS SUBSTRATES

(71) Applicant: KING ABDULLAH UNIVERSITY OF SCIENCE AND TECHNOLOGY, Thuwal (SA)

(72) Inventors: Husam Niman ALSHAREEF, Garland, TX (US); Xiangming XU, Thuwal (SA)

(21) Appl. No.: 17/909,807

(22) PCT Filed: Mar. 3, 2021
(86) PCT No.: PCT/IB2021/051777

§ 371 Date: Sep. 7, 2022

Related U.S. Application Data
(60) Provisional application No. 63/002,841, filed on Mar. 31, 2020.
(60) Provisional application No. 63/032,832, filed on Jun. 1, 2020.

(51) Int. Cl. H01L 33/00; H01L 33/04; H01L 33/32

(52) U.S. Cl. CPC H01L 33/007; H01L 33/04; H01L 33/32

(57) ABSTRACT

There is a method for making a high-performance opto-electronic device on an amorphous substrate. The method includes growing on a single-crystal substrate, a single-crystal, oxide film; applying a first chemical processing to the single-crystal, oxide film to obtain a first transferrable, single-crystal, chalcogenide film; transferring the transferrable, single crystal, chalcogenide film from the single-crystal substrate to an amorphous substrate or polycrystalline metal substrate; applying a second chemical processing to the transferrable, single-crystal, chalcogenide film to obtain a single-crystal, non-oxide film, wherein the single-crystal, non-oxide film is different from the transferrable, single-crystal, chalcogenide film; and growing a wide-bandgap semiconductor film using the single-crystal, non-oxide film as a seeding layer to obtain the opto-electronic device on the amorphous glass or polycrystalline metal substrate. The first chemical processing is different from the second chemical processing.

This application claims priority to U.S. Provisional Patent Application No. 63/002,841, filed on Mar. 31, 2020, entitled “A HEREDITARY PROCESS TECHNOLOGY FOR GROWING SINGLE-CRYSTALLINE FILMS ON AN AMORPHOUS SUBSTRATE,” and U.S. Provisional Patent Application No. 63/032,832, filed on Jun. 1, 2020, entitled “EPITAXIAL HEREDITARY PROCESSING OF SINGLE-CRYSTALLINE FILMS ON AMORPHOUS SUBSTRATES AND METHODS,” the disclosures of which are incorporated herein by reference in their entirety.

### BACKGROUND

### Technical Field

Embodiments of the subject matter disclosed herein generally relate to fabricating large-scale, large-area, single-crystal, films on an amorphous (or non-single crystalline) substrate, and more specifically, to growing non-oxide films directly on an amorphous substrate for use in opto-electronic and electronic devices.

### Discussion of the Background

Epitaxial film growth plays more and more significant roles to the modern information technology in the post-silicon generation. The wide bandgap semiconductor (GaN, SiC, et al) film growth contributes greatly to the high-performance laser-emitter diode (LED), power electronics, lasers, and photodetectors. The epitaxial growth of 2D semiconductors (MoS₂, WSe₂ et al) shows promising potential in the fabrication of very-large-scale integration of circuits, and multifunctional information process devices in the post-Moore age. Metallic epitaxial films would contribute greatly in the plasmonic devices and relevant applications.

Traditional methods of epitaxial film growth on a substrate are realized by direct deposition in a high-vacuum system, such as metal organic chemical vapor deposition (MOCVD), molecular beam epitaxy (MBE) and pulsed laser deposition (PLD). But these deposition methods require the strict lattice similarity between the epitaxial film and the single-crystalline substrate. Therefore, it has a very demanding requirement on the substrate. For example, the lattice mismatch between the film and the substrate should be less than 15%. Of course, the substrate should always have a perfect single-crystalline structure for these technologies. Such a strict limitation leads to a very expensive cost on the substrate. Also, the large-area (more than 300 mm) single-crystalline substrate size is not available.

Currently, there is no viable method for depositing single-crystalline epitaxial film on an amorphous (non-single-crystalline) substrate, such as glass and poly-crystalline metal substrate. These glass and metal substrates are much cheaper compared to the single-crystalline substrate. Also, very large-size glass and metal substrates are very easy to obtain at a very low price.

Thus, developing a new technology for the epitaxial film growth on glass or poly-crystalline metal substrates could significantly reduce the cost on the substrate. It can also broaden the application of the epitaxial device to a very large scale, such as large-area display and smart windows.

### SUMMARY

According to an embodiment, there is a method for making a high-performance opto-electronic device on an amorphous substrate. The method includes growing on a single-crystal substrate, a single-crystal, oxide film, applying a first chemical processing to the single-crystal, oxide film to obtain a first transferrable, single-crystal, chalcogenide film, transferring the transferrable, single crystal, chalcogenide film from the single-crystal substrate to an amorphous substrate or polycrystalline metal substrate, applying a second chemical processing to the transferrable, single-crystal, chalcogenide film to obtain a single-crystal, non-oxide film, wherein the single-crystal, non-oxide film is different from the transferrable, single-crystal, chalcogenide film, and growing a wide-bandgap semiconductor film using the single-crystal, non-oxide film as a seeding layer to obtain the opto-electronic device on the amorphous glass or polycrystalline metal substrate. The first chemical processing is different from the second chemical processing.

According to another embodiment, there is an opto-electronic device that includes an amorphous substrate or a polycrystalline metal substrate, a single-crystal, non-oxide film located directly on the amorphous substrate or the polycrystalline metal substrate, a GaN buffer layer located directly over the single-crystal, non-oxide film, an n-type GaN layer located directly over the GaN buffer layer, a multi-quantum well layer located over the N-type GaN layer, and a p-type GaN layer located over the multi-quantum well layer.

According to yet another embodiment, there is a method for forming an opto-electronic device. The method includes transferring a transferrable, single-crystal, chalcogenide film from a single-crystal substrate to an amorphous substrate, applying a chemical processing to the transferrable, single-crystal, chalcogenide film to obtain a single-crystal, non-oxide film, wherein the single-crystal, non-oxide film is different from the transferrable, single crystal, chalcogenide film, and forming an additional film on the single-crystal, non-oxide film to obtain the opto-electronic device.

### BRIEF DESCRIPTON OF THE DRAWINGS

The accompanying drawings, which are incorporated in and constitute a part of the specification, illustrate one or more embodiments and, together with the description, explain these embodiments. In the drawings:

FIG. 1 illustrates a pulse laser deposition system for forming a single-crystal oxide film;

FIG. 2 is a schematic of a tube furnace used for transforming the single-crystal, chalcogenide film into a single-crystal, non-oxide film or for transforming a first single-crystal, non-oxide film into a second single-crystal, non-oxide film;

FIG. 3A illustrates the 2θ scan of the epi-MoO₂ (epi-MoO₂) film, FIG. 3B is the pole figure epi-MoO₂ film, which shows that the (011) MoO₂ in-plane lattice planes having a six-fold rotation symmetry, and FIG. 3C illustrates the out-of-plane and in-plane orientation relationship between the epi-MoO₂ film and the (001) sapphire substrate;

FIG. 4A illustrates the 2θ scan of the epi-Mo₂C film, FIG. 4B is the phi scan of the epi-Mo₂C film, and FIG. 4C illustrates the out-of-plane and in-plane orientation relationship between the epi-Mo₂C film and the (001) sapphire substrate;

FIG. 5A illustrates the 2θ scan of the epi-MoN film, FIG. 5B is the phi scan of the epi-MoN film, and FIG. 5C illustrates the out-of-plane and in-plane orientation relationship between the epi-MoN film and the (001) sapphire substrate;

FIG. 6A is the 2θ scan of the epi-MoS₂ film, FIG. 6B is the phi scan of the epi-MoS₂ film, and FIG. 6C shows the out-of-plane and in-plane orientation relationship between the epi-MoS₂ film and the (001) sapphire substrate;

FIG. 7A is the 2θ scan of the epi-ZnO film, FIG. 7B is the phi scan of the epi-ZnO film, and FIG. 7C shows the out-of-plane and in-plane orientation relationship between the epi-ZnO film and the (001) sapphire substrate;

FIG. 8A is the 2θ scan of the epi-MoS₂ film, FIG. 8B is the phi scan of the epi-MoS₂ film, and FIG. 8C shows the out-of-plane and in-plane orientation relationship between the epi-ZnS film and the (001) sapphire substrate;

FIG. 9A is the 2θ scan of the epi-In₂O₃ film, FIG. 9B is the phi scan of the epi-In₂O₃ film, and FIG. 9C shows the out-of-plane and in-plane orientation relationship between the epi-In₂O₃ film and the (001) sapphire substrate;

FIG. 10A is the 2θ scan of the Epi-In₂S₃ film, FIG. 10B is the phi scan of the cubic In₂S₃ film, and FIG. 10C shows the out-of-plane and the in-plane orientation relationship between the In₂S₃ and the Al₂O₃ substrate;

FIG. 11 illustrates a chemical conversion process of a single-crystal, chalcogenide film to a single-crystal, non-oxide film;

FIG. 12A shows the XRD 2θ-scan of the single-crystal MoS₂ film out-of-plane lattice orientation, FIG. 12B shows the XRD 2θ-scan of the MoS₂ film out-of-plane lattice orientation, and FIGS. 12C and 12D show the XRD 2θ-scan and phi scan of the MoN film showing the out-of-plane lattice orientation is along the (001) direction and the in-plane (202) lattice has an orientation with 6-fold rotation symmetries;

FIGS. 13A to 13F illustrate a method of making an opto-electronic device by transforming a single-crystal layer into a single-crystal, chalcogenide layer while on a single-crystal substrate, transferring the single-crystal, chalcogenide layer onto an amorphous substrate, and transforming the single-crystal, chalcogenide layer into a single-crystal, non-oxide layer, which is different from the single-crystal, chalcogenice layer;

FIG. 14 shows an opto-electronic device made with the method illustrated in FIGS. 13A to 13F;

FIG. 15 illustrates the lattice matching of the single-crystal, non-oxide layer and a GaN layer that is deposited on top of the single-crystal, non-oxide layer; and

FIG. 16 is a flowchart of a method for making an opto-electronic device based on the processes illustrated in FIGS. 13A to 13F.

### DETAILED DESCRIPTION

The following description of the embodiments refers to the accompanying drawings. The same reference numbers in different drawings identify the same or similar elements. The following detailed description does not limit the invention. Instead, the scope of the invention is defined by the appended claims. The following embodiments are discussed, for simplicity, with regard to a nitride based film that may be used in an opto-electronic device. However, the embodiments discussed herein are not limited to nitride based films, as other non-oxide films may be manufactured by the same methods.

Reference throughout the specification to “one embodiment” or “an embodiment” means that a particular feature, structure or characteristic described in connection with an embodiment is included in at least one embodiment of the subject matter disclosed. Thus, the appearance of the phrases “in one embodiment” or “in an embodiment” in various places throughout the specification is not necessarily referring to the same embodiment. Further, the particular features, structures or characteristics may be combined in any suitable manner in one or more embodiments.

According to an embodiment, there is method for forming a single-crystal oxide film on a single-crystal substrate, chemically converting the single-crystal oxide film into a transferrable epitaxial Van Der Waal chalcogenide, single-crystal film, transferring the epitaxial chalcogenide single-crystal film onto an amorphous substrate, and then chemically converting the chalcogenide single-crystal film into another non-oxide, single-crystal film such as nitride, carbide et al. The non-oxide, single-crystal nitride film may be used as a seeding layer on the amorphous substrate for growing a high-performance wide bandgap semiconductor film for an opto-electronic device. The detail of chemical conversion of various epitaxial films on both single crystalline and amorphous substrates are now discussed with regard to the figures.

A chalcogenide material is a chemical compound consisting of at least one chalcogen anion and at least one more electropositive element. Although all group 16 elements of the periodic table are defined as chalcogens, the term chalcogenide is more commonly reserved for sulfides, selenides, tellurides, and polonides.

In one embodiment, performing a sulfurization process of an epitaxial MoO₂ film could generate epitaxial MoS₂ film. Thus, through performing various chemical conversions of epitaxial oxide films, the inventors developed an epitaxial heredity process. This epitaxial heredity could enable to grow various epitaxial films, at a low cost, on large-size amorphous glass or poly-crystalline metal substrates. Besides, even though there is a big lattice mismatch (as large as 30%) between the film and the substrate, the epitaxial heredity also could enable one skilled in the art to grow epitaxial non-oxide films on single-crystalline substrates.

The inventors have observed that heredity is a phenomenon that exists not only in bioscience, where the parents' traits pass onto their offspring, but also in material science, for example in the chemical conversion process. Specifically, epitaxial phases are inherited from oxides to other compounds in many chemical conversion processes. This observation can be used to achieve a predictable control of the product crystal phase and orientation in the chemical transformation. The inventors have realized that this phenomenon can be used to obtain some high-quality epitaxial non-oxide compound films, some of which are very challenging to achieve through traditional growth methods. These high-quality, single-crystal, non-oxide films may include metallic MXene-like film (Mo₂C and MoN), two-dimensional semiconductors (MoS₂, In₂S₃), and a wide-band-gap semiconductor (ZnS).

The inventors have also observed the atavism inheritance of the epitaxial phase, which eliminates the requirement of the single crystalline substrate for epitaxial film growth. This enables the inventors to grow a single-crystalline film on an amorphous substrate. Based on the above observation, high-quality, single-crystalline, wide-bandgap films could be grown on this non-single-crystalline substrate. The light-emitting diode's performance based on this wide-bandgap semiconductor can be compatible with that based on films grown on standard single crystalline substrate. Thus, the epitaxial heredity in the grown films can be used to achieve controllability and predictability of the product structure in chemical conversion, overcomes the limitation of traditional epitaxial growth methods, and enables wide application of superconductivity, photonics and electronics on non-single crystalline substrates.

The chemical conversion process, especially the solid-gas reaction process, has been sufficiently investigated in terms of product composition and structure, reaction kinetics and rate, mass transfer or diffusion through the interfacial and in the bulk. However, the crystallographic orientation relationship between the solid precursor or reactant and the solid product catches little attention in the relevant research fields. The reason might stem from that the study object in this field is granular powder. These granules are staying together with random crystalline orientations. Thus, there is still no definite information in the field for comparing the orientation relationship between the particle reactant and the product.

A method for growing a single-crystal, MoS₂ film on a single-crystal substrate has been discussed in WIPO application WO 2019/142035, the entire content of which is incorporated herein. This application belongs to the assignee of the present application. In this WIPO application, the term “epitaxial” is understood to mean “a single crystal.” The same convention is adopted in the present application.

The method in the WIPO application described how to obtain single crystalline 2D MoS₂ films at large area, by using an epitaxial MoO₂ film as the precursor for the sulfurization process. The traditional MoS₂ growth method could only grow isolated flake islands or continuous polycrystalline films. The novelty in the WIPO application is that the sulfurization of the epitaxial MoO₂ film could realize continuous single crystalline MoS2 films. Thus, the method disclosed in the WIPO publication provides simultaneous (1) thickness control (one atomic layer at a time) and (2) continuous single-crystalline MoS₂ film at a large scale.

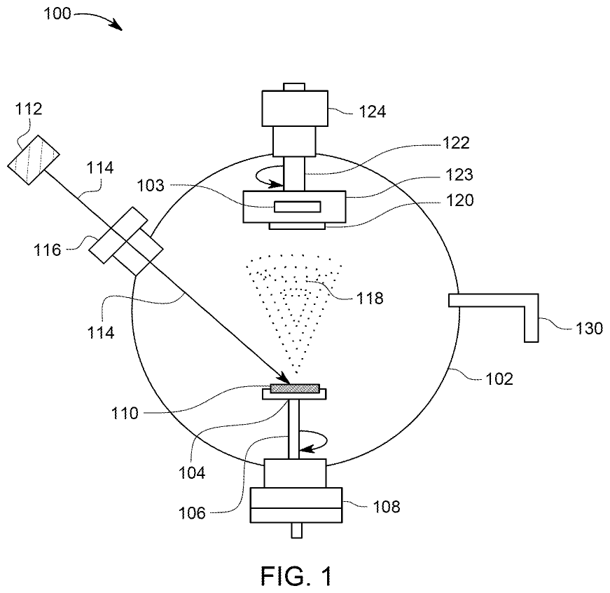

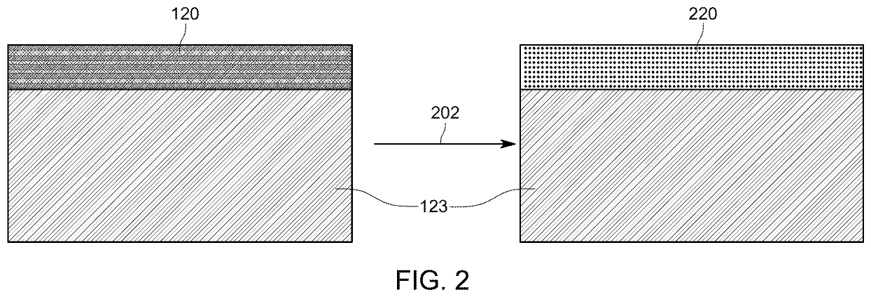

A pulsed laser deposition (PLD) system used to grow various oxide epitaxial films (such as MoO₂, ZnO, In₂O₃) is now discussed with regard to FIG. 1. Although the PLD method is discussed herein, one skilled in the art would understand that other methods may be used, for example, sputtering deposition, molecular beam epitaxy (MBE) or metalorganic vapor phase epitaxy (MOCVD) as long as the formed oxide films are single-crystal. As illustrated in FIG. 1, a PLD system 100 includes a PLD chamber 102 that holds a target support 104. Target support 104 may be a plate that is attached with an axle 106 to a motor 108. The motor 108 may be located outside the PLD chamber 102. The target support 104 holds the target material 110, which could be various oxide bulk plates (MoO₃, ZnO or In₂O₃). The motor 108 may rotate the target support 104 so that the target material 110 is rotated inside the PLD chamber 102.

A pulsed laser device 112, for example, a KrF₂ laser, may be used to generate a beam 114 that is directed through a port 116 inside the PLD chamber 102. The beam 114 interacts with the target material 110 and atoms or molecules of the precursor oxide material are ablated. The ablated atoms and/or molecules 118 travel to a substrate 123, to form the oxide layers 120. The substrate 123 may be a single-crystal material, for example, a single-crystal Al₂O₃. The substrate 123 is attached to a holder 122, which is connected to a motor 124. While motor 124 may be located outside the PLD chamber 102, the substrate 123 and the MoO₂ film 120 are located inside the PLD chamber and both are located above the target material 110, so that the ablated atoms and/or molecules 118 travel vertically upwards toward the substrate 123. Thus, the ablated atoms and/or molecules 118 deposit, layer-by-layer, as the oxide film 120 onto the substrate 123. Because the substrate 123 is selected to be a single-crystal material, the deposited oxide film grows having a single-crystal structure. The substrate 123 may have a heater 103 for heating the substrate to a desired temperature (e.g., 400° C. for growing MoO₂, 600° C. for growing ZnO, 500° C. for growing In₂O₃). The PLD chamber 102 may also have a port 130 through which oxygen or other gases may be inserted into the PLD chamber 102. In one application, the pulsed laser energy of the laser device 112 is about 210 mJ, and the pressure of the oxygen gas is about 10 mtorr for MoO₂ growth, 50 mtorr for ZnO growth, and 10 mtorr for In₂O₃ growth.

A specific implementation of this step may use a 2-inch (001) Al₂O₃ substrate 123. Before applying the PLD process to this substrate, it was cleaned sequentially with acetone, IPA, and DI water, for 5 min in each solvent, combined with sonication. Then the substrate 123 was attached to the corresponding support element 122 (see FIG. 1).

Next, the precursor epitaxial oxide film 120 is chemically converted to a non-oxide, single-crystal film. The phase conversion process may include one of nitridation, sulfurization, selenylation, telluridation, or carbonization. For this specific embodiment, the epitaxial oxide film was placed inside a tube furnace with special atmosphere such as chalcogen vapor, CH₄ and NH₃ reaction gases. The converted non-oxide films are verified to also be epitaxial, i.e., single-crystal.

A specific implementation of the chemical conversion process is discussed with regard to FIG. 2. The precursor epitaxial oxide film 120 was loaded in the reactor (could be a tube furnace or a sealed chamber). After providing sulfur (S) vapor (or CH₄, NH₃) in the reactor, the high-temperature chemical conversion process 202 was performed. Specific reaction temperature/time for the chemical conversion is 900° C./3 hrs from MoO₂ to Mo₂C (in CH₄/H₂ atmosphere), 900° C./3 hrs from MoO₂ to MoN (in NH₃ atmosphere), 900° C./1 hrs from MoO₂ to MoS₂ (in S/Ar atmosphere), 700° C./8 hrs from ZnO to ZnS (in S/Ar atmosphere), 600° C./6 hrs from In₂O₃ to In₂S₃ (in S/Ar atmosphere). Particularly, for the conversion from MoO₂ to MoS₂, the MoO₂ film need to be pretreated with a capping layer annealing process to further increase the MoO₂ epitaxial quality, so that the MoS₂ film could be converted with a single in-plane and out-of-plane crystalline orientations.

In order to explore the epitaxial heredity phenomena, epitaxial features of both the reactant oxide films and the product non-oxide films have been clarified and compared through a high-resolution X-ray diffraction (HR-XRD) techniques. All the out-of-plane θ-2θ scans and in-plane phi scans and pole figure of these films were obtained through HR Thin-film X-Ray equipment, with a Cu Kα x-ray source. The ψ angle is the angle between the lattice plane parallel to the substrate surface and the in-plane lattice plane.

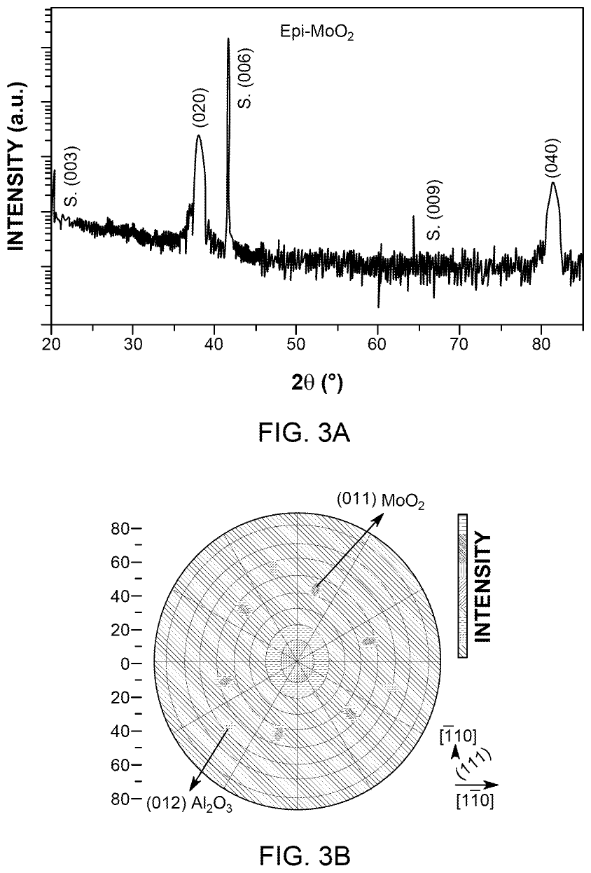

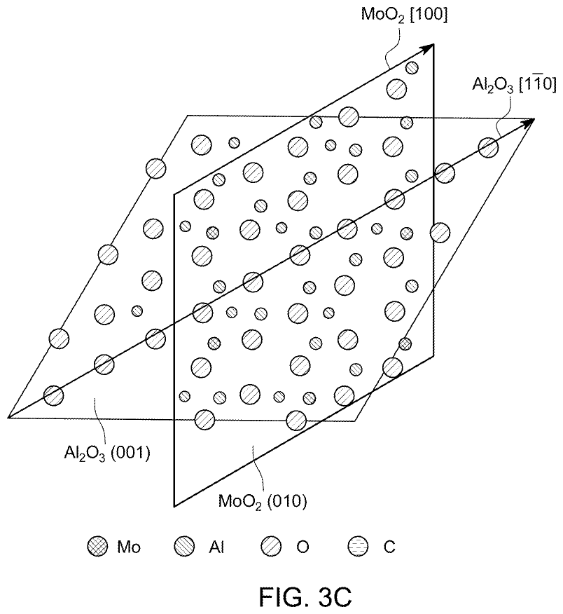

FIGS. 3A to 3C characterize the monoclinic MoO₂ (space group: P21/c (14)) epitaxial film gown on a (001) sapphire substrate. More specifically, FIG. 3A is the 2θ scan of epitaxy MoO₂ (epi-MoO₂) film, showing the out-of-plane orientation relationship: (010) MoO₂//(001) Al₂O₃. FIG. 3B is the pole figure epi-MoO₂ film, which shows both (011) MoO₂ in-plane lattice planes having a six-fold rotation symmetry. It has a 30° offset to the (012) Al₂O₃ in-plane lattice plane. From this, it can be deduced that the precursor in-plane rotation relationship is [001] MoO₂//[11̅0] Al₂O₃. Both the out-of-plane and in-plane orientation relationship between the epi-MoO₂ film and the (001) sapphire substrate are clarified in FIG. 3C.

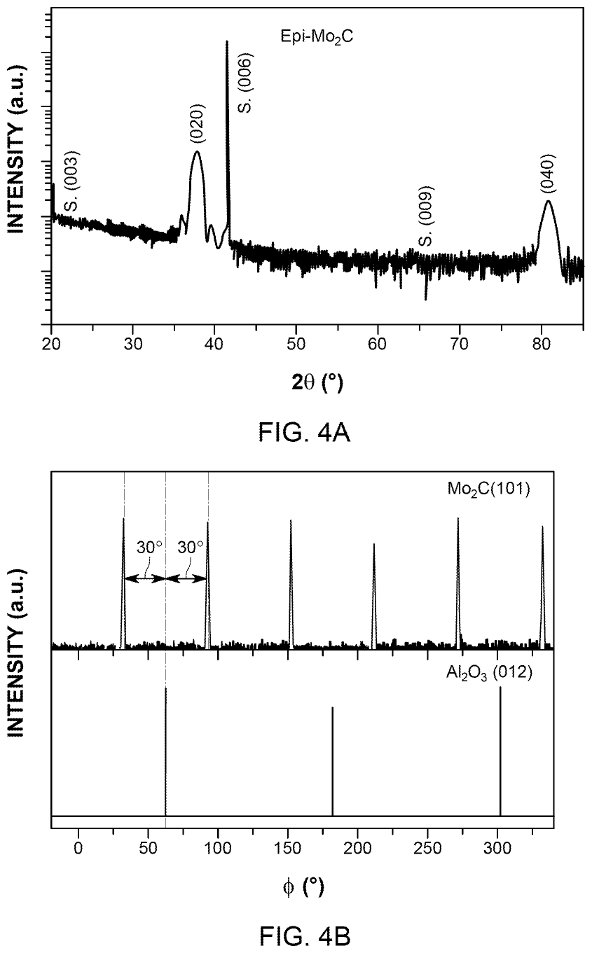

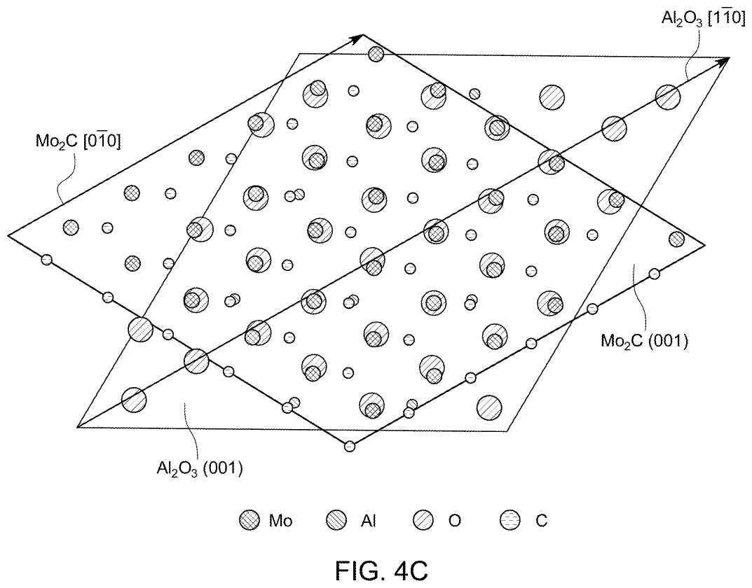

Through a high-temperature carbonization of the epi-MoO₂ film in the CH₄/H₂ atmosphere, the inventors have obtained the Mo₂C film. Also, the inventors confirmed that the obtained film is epi-Mo₂C having a hexagonal structure with space group: P63/mmc (194). FIG. 4A provides an XRD characterization of the epi-Mo₂C film. More specifically, FIG. 4A is the 2θ scan of the epi-Mo₂C film, showing out-of-plane orientation relationship: (001) Mo₂C//(001) Al₂O₃, inherited from (010) MoO₂//(001) Al₂O₃. FIG. 4B is the phi scan of the epi-Mo₂C film, which shows both (101) Mo₂C in-plane lattice planes having six-fold rotation symmetry. It also has a 30° offset to the (012) Al₂O₃ in-plane lattice plane. It can be deduced that the precursor in-plane rotation relationship is [01̅0] Mo₂C//[11̅0] Al₂O₃, which is inherited from the [001] MoO₂//[11̅0] Al₂O₃. Both the out-of-plane and in-plane orientation relationship between the epi-Mo₂C film and the (001) sapphire substrate are illustrated in FIG. 4C. Based on this, the inventors discovered the heredity of the epitaxy in the complete carbonization process.

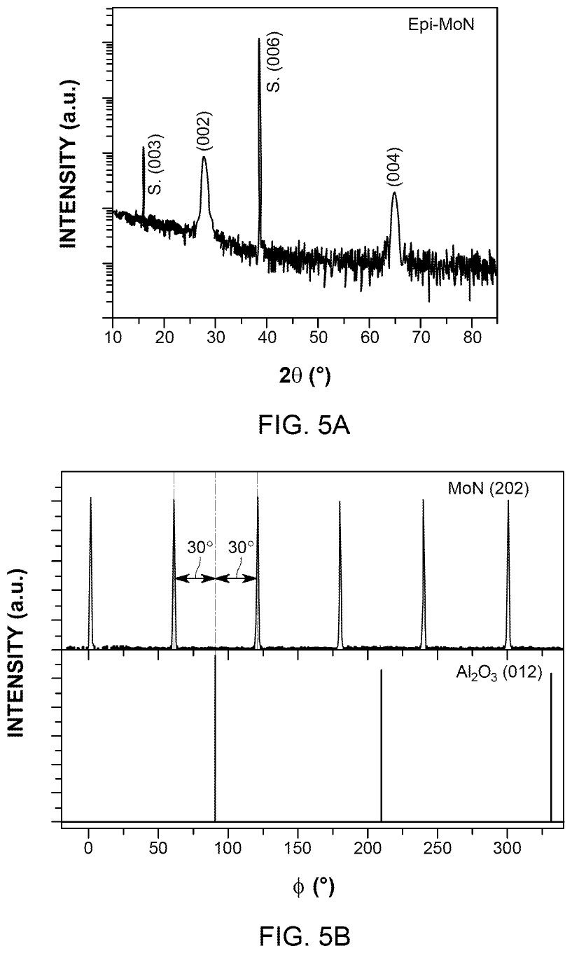

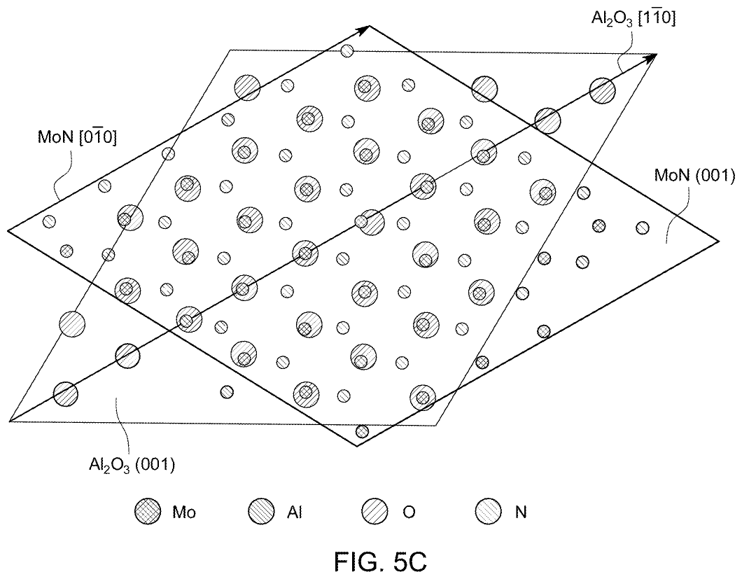

Through high-temperature nitridation of epi-MoO₂ film in the NH₃ atmosphere, the inventors have also obtained a MoN film. Also, the inventors confirmed that the obtained MoN film is an epi-MoN with hexagonal structure with space group: P63/mmc (194). FIGS. 5A to 5C show the XRD characterization of the epi-MoN film. More specifically, FIG. 5A is the 2θ scan of the epi-MoN film, showing the out-of-plane orientation relationship: (001) MoN//(001) Al₂O₃, which is inherited from the (010) MoO₂//(001) Al₂O₃. FIG. 5B is the phi scan of the epi-MoN film. From these graphs, it can be seen that both (101) MoN in-plane lattice planes have a six-fold rotation symmetry. It also has a 30° offset to the (012) Al₂O₃ in-plane lattice plane. The inventors have deduced that the precursor in-plane rotation relationship is [01̅0] MoN//[11̅0] Al₂O₃, which is inherited from the [001] MoO₂//[11̅0] Al₂O₃. Both the out-of-plane and in-plane orientation relationship between the epi-MoN film and the (001) sapphire substrate are illustrated in FIG. 5C. Thus the inventors have also proven the epitaxial heredity in the nitridation process.

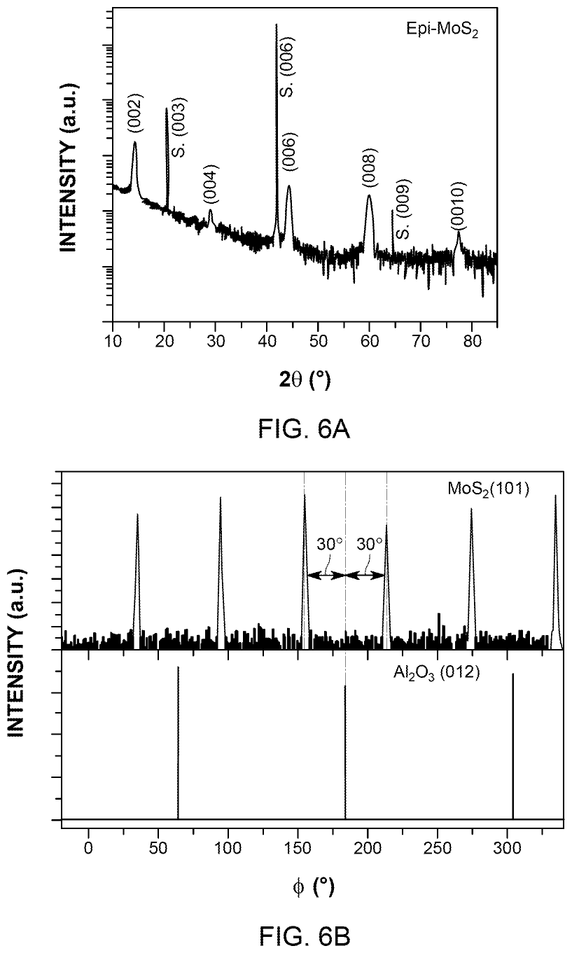

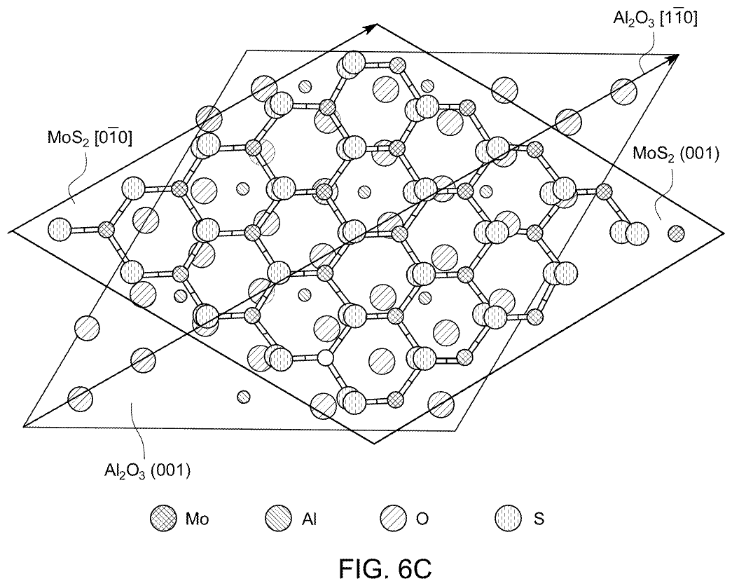

Through high-temperature sulfurization of the epi-MoO₂ film (the oxide film need go through a CLAP process to enhance the epi-quality) in the sulfur vapor atmosphere, the inventors have also obtained an MoS₂ film. The inventors confirmed that the obtained MoS₂ film is an epi-MoS₂ with hexagonal structure with space group: P63/mmc (194). FIGS. 6A to 6C shows the XRD characterization of the epi-MoS₂ film. More specifically, FIG. 6A is the 2θ scan of the epi-MoS₂ film, showing the out-of-plane orientation relationship: (001) MoS₂//(001) Al₂O₃, which was inherited from the (010) MoO₂//(001) Al₂O₃. FIG. 6B is the phi scan of the epi-MoS₂ film, and it could be seen that both (101) MoS₂ in-plane lattice planes have a six-fold rotation symmetry. It also has a 30° offset to the (012) Al₂O₃ in-plane lattice plane. The inventors have deduced that the precursor in-plane rotation relationship is [01̅0] MoS₂//[11̅0] Al₂O₃, which is inherited from [001] MoO₂//[11̅0] Al₂O₃. Both the out-of-plane and in-plane orientation relationship between the epi-MoS₂ film and the (001) sapphire substrate are shown in FIG. 6C. Therefore, the inventors have also confirmed the epitaxial heredity in the 3D structure oxide to the 2D Van der Waal layered chalcogenide films.

The epitaxial heredity phenomenon happens not only for the sulfurization, nitridation, and carbonization of the MoO₂ film, but also for the chemical conversion of other epitaxial oxide films, as, for example, the wurtzite-ZnS (hexagonal) material. This material is a wide bandgap semiconductor with a direct bandgap (3.7 eV) and a high exciton binding energy (38 meV). Therefore, it is very promising for optoelectronic applications. However, the hexagonal wurtzite phase is metastable when compared to its cubic zinc-blende phase, and it is more challenging to grow pure hexagonal phase through traditional direct deposition process. Thus, the inventors have grown a ZnS film with pure epitaxial hexagonal phase by chemical conversion of the epitaxial hexagonal structure of a ZnO film.

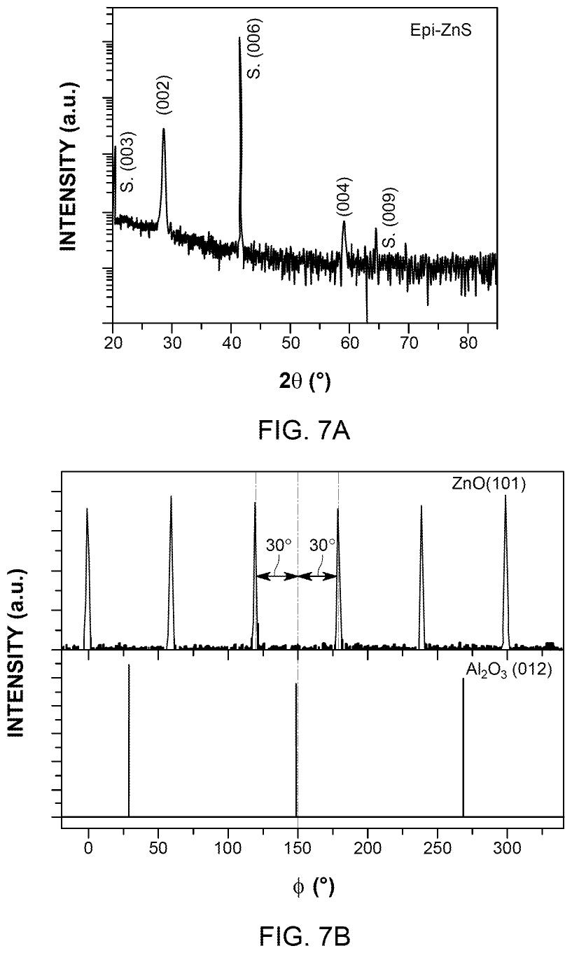

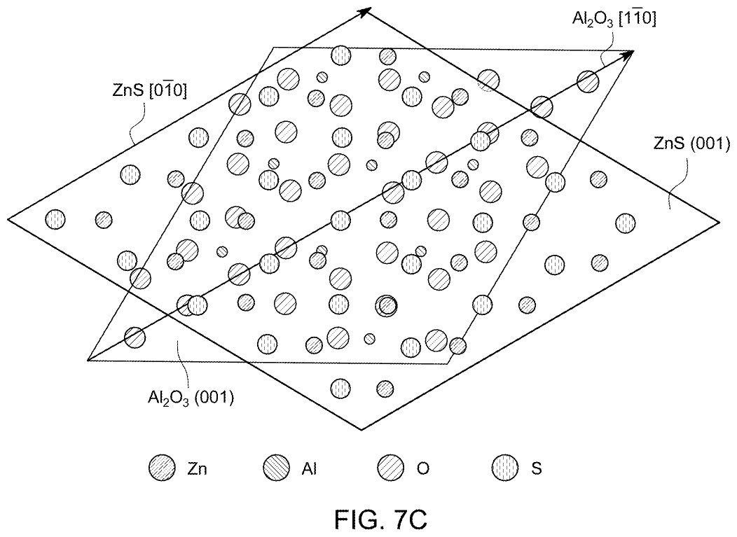

The ZnO film (space group: P63mc (186)) with the epitaxial hexagonal phase on (001) sapphire substrate was confirmed by XRD measurements as illustrated in FIGS. 7A to 7C. FIG. 7A is the 2θ scan of the epi-ZnO film, showing out-of-plane orientation relationship: (001) ZnO//(001) Al₂O₃. FIG. 7B is the phi scan of the epi-ZnO film, from which it can be seen that both (011) ZnO in-plane lattice planes have a six-fold rotation symmetry. It has a 30° offset to the (012) Al₂O₃ in-plane lattice plane. The inventors have determined that the precursor in-plane rotation relationship is [01̅0] ZnO//[11̅0] Al₂O₃. Both the out-of-plane and in-plane orientation relationship between the epi-ZnO film and the (001) sapphire substrate are shown in FIG. 7C.

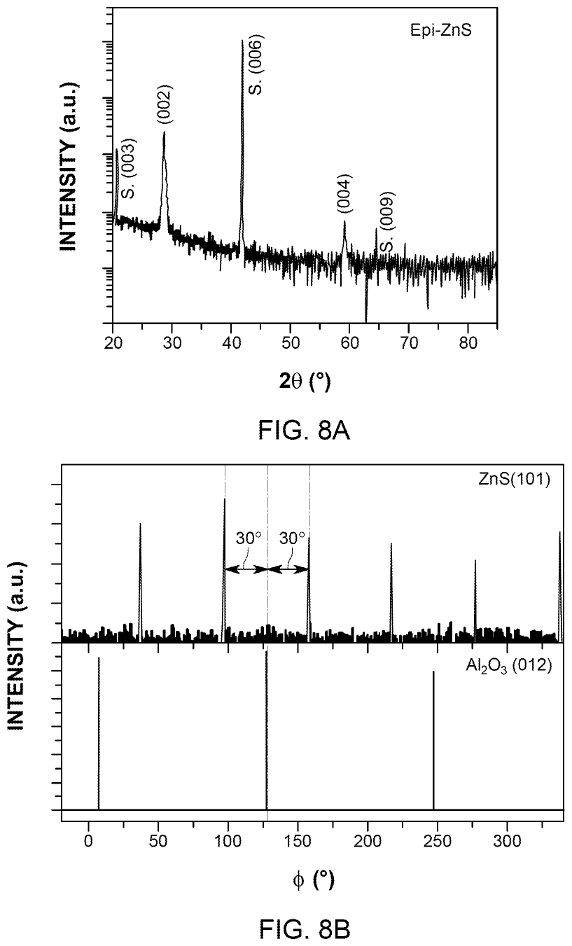

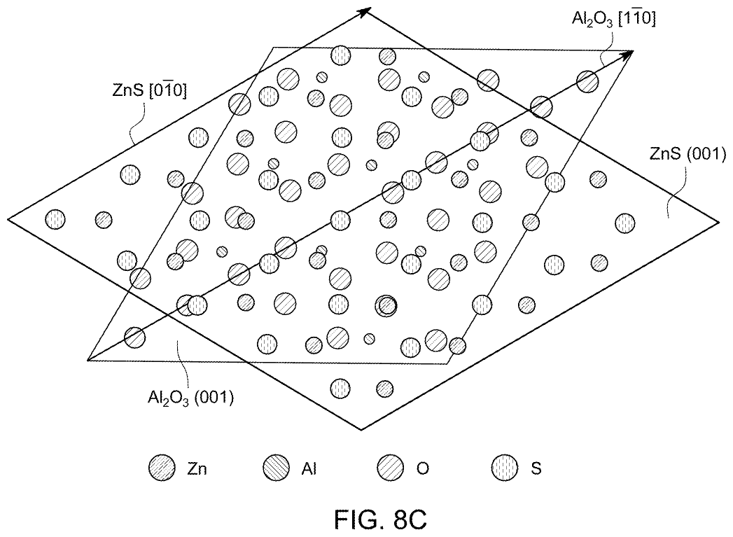

Through a 7-hrs high-temperature sulfurization process of the epi-ZnO film in the sulfur vapor atmosphere, the inventors have obtained the ZnS film. Also, the inventors have confirmed that the obtained ZnS film is the epi-ZnS film with hexagonal structure with space group: P63mc (186). FIGS. 8A to 8C show the XRD characterization of the epi-ZnS film. FIG. 8A is the 2θ scan of the epi-MoS₂ film, showing the out-of-plane orientation relationship: (001) ZnS//(001) Al₂O₃, which is inherited from (010) ZnO//(001) Al₂O₃. FIG. 8B is the phi scan of the epi-MoS₂ film, and it can be seen from this figure that both the (101) ZnS in-plane lattice planes have a six-fold rotation symmetry. It also has a 30° offset to the (012) Al₂O₃ in-plane lattice plane. The inventors have determined that the precursor in-plane rotation relationship is [01̅0] ZnS//[11̅0] Al₂O₃, which is inherited from [001] ZnO//[11̅0] Al₂O₃. Both the out-of-plane and in-plane orientation relationship between the epi-ZnS film and the (001) sapphire substrate are shown in FIG. 8C. Therefore, the inventors have also confirmed the epitaxial heredity in the sulfurization of the ZnO film.

The In₂S₃ material is another promising semiconductor with experimentally confirmed excellent optoelectronic properties and theoretically predicted ferroelectricity. The inventors have obtained continuous pure-phase metastable cubic Epi-In₂S₃ film for the first time, through the principle of epitaxy heredity discussed above.

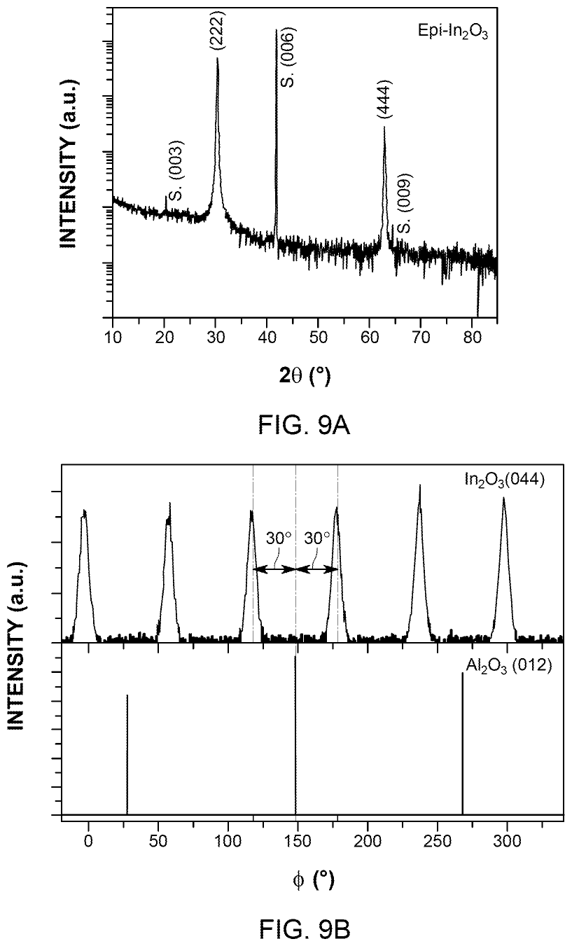

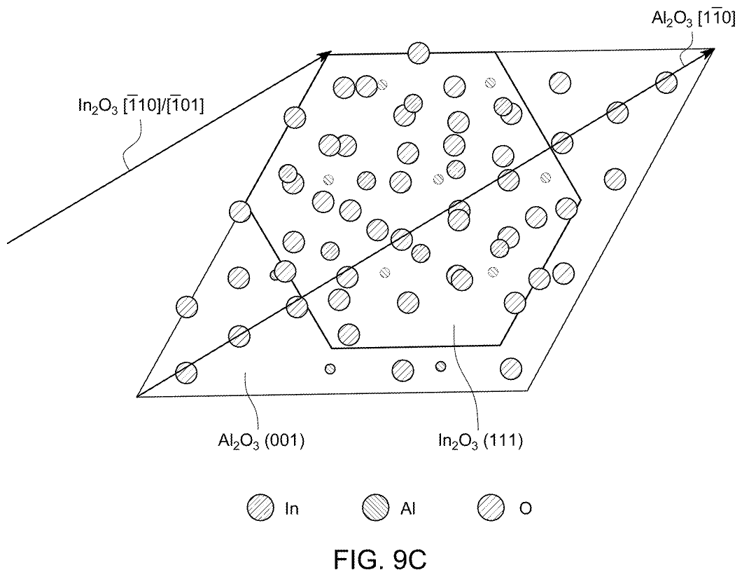

The precursor In₂O₃ film was successfully grown, and its epitaxial cubic phase with space group: Ia-3 (206) was confirmed by XRD 2θ scan shown in FIG. 9A and the phi scan shown in FIG. 9B. The out-of-plane and in-plane orientation relationship were also determined as being: (111) In₂O₃//(001) Al₂O₃ with [1̅10] In₂O₃//[11̅0] Al₂O₃, as illustrated in FIG. 9C.

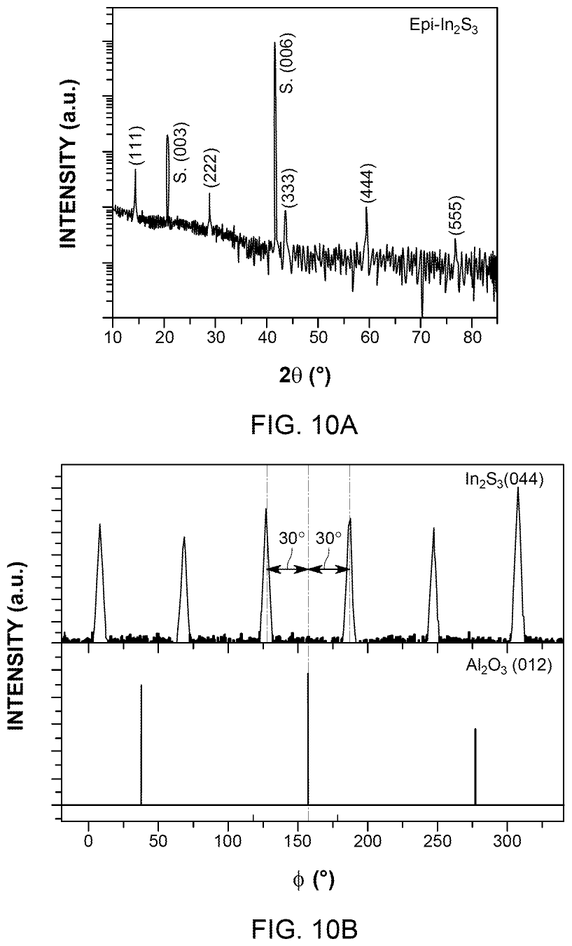

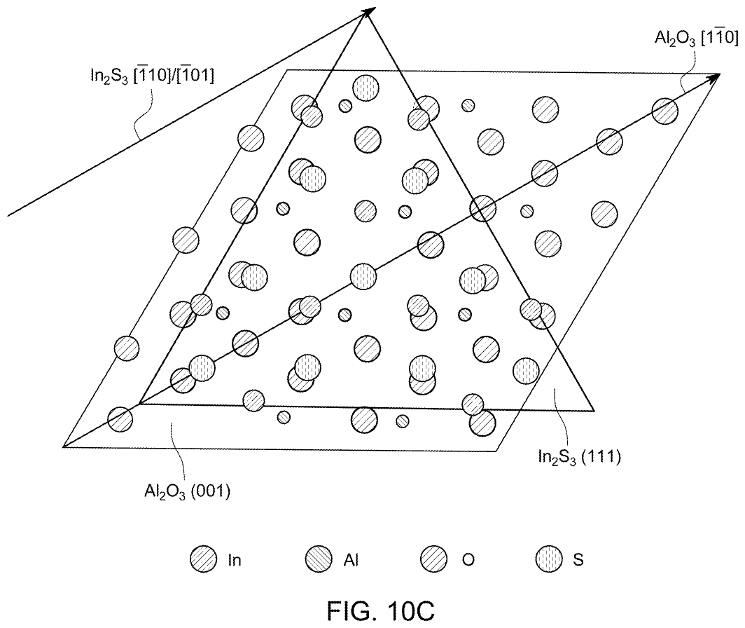

However, for the sulfurization process, it takes a longer time (70 hrs, as discussed later) to convert the In₂O₃ film to the In₂S₃ film. FIG. 10A shows the 2θ scan of the Epi-In₂S₃ film (space group: Fd-3m (227)), showing that the out-of-plane orientation is only along cubic {111} In₂S₃ direction. FIG. 10B shows the phi scan plot of the (044) cubic In₂S₃ and exhibits six spots (two domains with three spots) separated azimuthally by an angle of 60°. Through the calculation of the stereographic projection based on the 30° offset between the (044) cubic In₂S₃ and the (012) Al₂O₃, the inventors have determined that the out-of-plane and the in-plane orientation relationship is (111) In₂S₃//(001) Al₂O₃ and [1̅10] In₂S₃//[11̅0] Al₂O₃, as illustrated in FIG. 10C, which is inherited from the epitaxial cubic In₂O₃ film on the (001) Al₂O₃ substrate.

Thus, the inventors have tried different types of chemical conversions, such as carbonization, nitridation, and sulfurization, using three oxide precursors Epi-MoO₂, Epi-ZnO, and Epi-In₂O₃, and achieved five final products Epi-Mo₂C, Epi-MoN, Epi-MoS₂, Epi-ZnS, and Epi-In₂S₃. Three different crystalline structures were involved, such as monoclinic, hexagonal, and cubic.

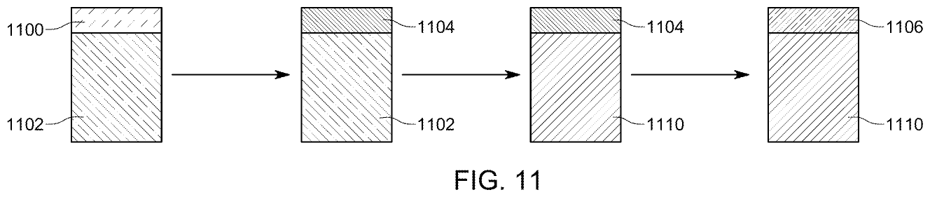

To confirm that the crystalline phase and orientation of the Epi-product after conversion is inherited from the Epi-precursor instead of being confined by the single-crystalline substrate, the inventors explored the epitaxial heredity on a non-single-crystalline substrate. The conversion process is schematically displayed in FIG. 11. Firstly, the Epi-MoO₂ film 1100 is deposited on the single-crystalline Al₂O₃ substrate 1102. Then, the Epi-MoO₂ film 1100 was sulfurized into the Epi-MoS₂ film 1104. Then, a PDMS-assistant transfer process was performed to transfer the MoS₂ film 1104, from the single-crystalline substrate 1102, to the amorphous (Amo-) SiO₂/(001) Si⁺⁺ substrate 1110. The single-crystal MoS₂ film 1104 on the Amo-substrate 1110 still retains its epitaxial structure. Finally, a nitridation process was performed to convert the single-crystal MoS₂ film 1104 to the single-crystal MoN film 1106 on the Amo-substrate 1110. The final MoN film 1106 shows a single crystalline structure even on this Amo-substrate. This process indicates that the epitaxial heredity phenomenon has no requirement on the crystallinity of the support substrate.

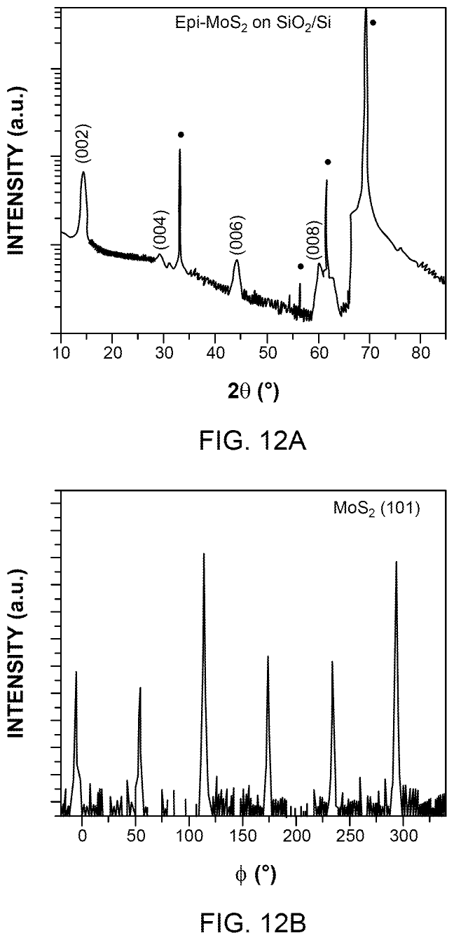

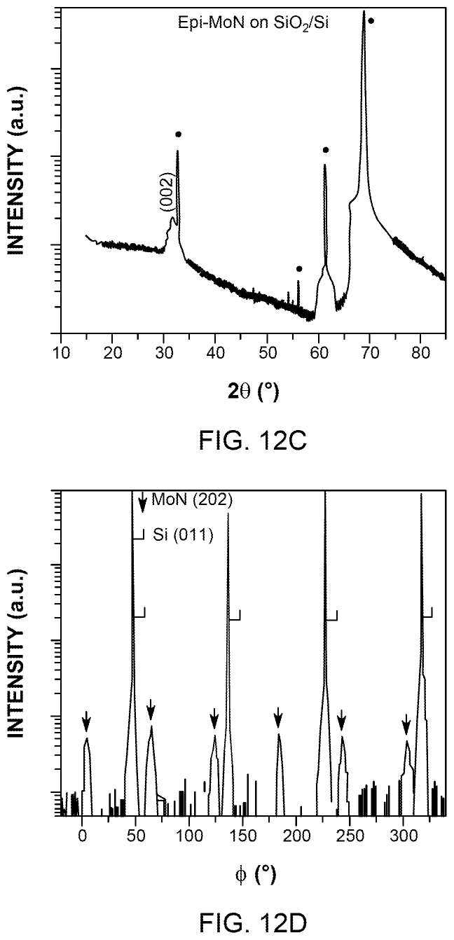

The XRD 2θ-scan in FIG. 12A confirms that the MoS₂ film out-of-plane lattice orientation is only along the (001) direction, except for the (001) peak of the Si⁺⁺ substrate underneath the 300 nm thick Amo-SiO₂ layer. The XRD phi scan in FIG. 12B confirms the MoS₂ film in-plane (101) lattice orientation with 6-fold rotation symmetries. The highly ordered in-plane and out-of-plane lattice orientation confirmed the MoS₂ epitaxial feature after transferred onto the Amo-substrate. The XRD 2θ-scan and phi scan in FIGS. 12C and 12D confirm that the MoN film out-of-plane lattice orientation is also only along the (001) direction and the in-plane (202) lattice has an orientation with 6-fold rotation symmetries, confirming the MoN epitaxy feature after the nitridation on the Amo-substrate.

The various chemical conversion processes, discussed above with regard to the figures, performed on different epitaxial oxide films, involved sulfurization, carbonization and nitridation of three epitaxial oxide precursors (MoO₂, ZnO, and In₂O₃). After the conversion, the inventors obtained several different epitaxial products. They are metallic Mo₂C and MoN, layered semiconductor MoS₂, wide-bandgap semiconductor ZnS, and ferroelectric semiconductor In₂S₃. These various conversion processes touched three different crystalline structures (monoclinic, hexagonal, and cubic). Through performing the epitaxial film chemical conversion process on an amorphous substrate, the inventors excluded the possibility that the product epitaxy feature is confined by the support substrate. This process enables the possibility of growing a single-crystalline film on an amorphous substrate, which is not possible, according to the inventors' knowledge, through the traditional epitaxial growth methods.

In this regard, it is noted that the existing devices are made using homo-epitaxy and hetero-epitaxy, which are traditional methods for single-crystalline film growth. They require that not only the substrate be the single-crystalline structure, but also a small lattice mismatch between the support substrate and the grown films. Recently, van der Waals epitaxy, remote epitaxy and lateral epitaxy growth methods were developed for growing different kinds of two and three-dimensional films or junctions. But these newer methods also require the substrate to be single crystalline and with a big or small lattice mismatch, depending on the process. Through the scientific phenomena about the epitaxial heredity, the inventors developed a method where a high-quality single-crystalline film could be grown on the amorphous substrate. This technology could, therefore, enable the growth of single-crystalline films independent of the type of substrate crystallinity or magnitude of its lattice constant. Furthermore, using this obtained single-crystalline film as an interlayer on an amorphous substrate, high-quality wide-bandgap single-crystalline semiconductor films can be grown on any surface-flat substrates. This could enable high-performance semiconductor devices on any non-single-crystalline substrates

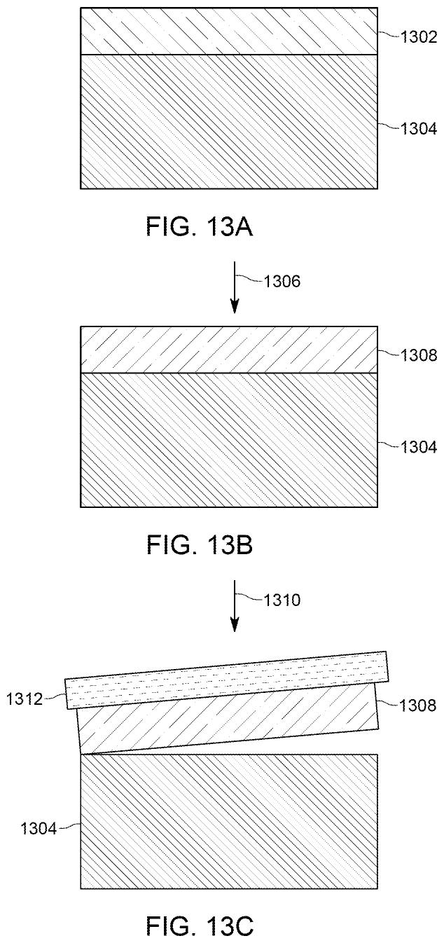

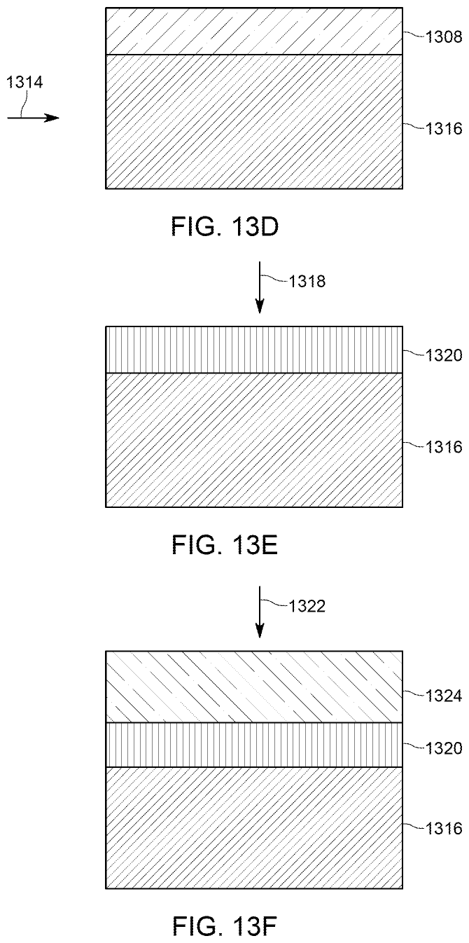

Some details about the processes of making the various films illustrated in FIGS. 3C, 4C, 5C, 6C, 7C, 8C, 9C, and 100 are now discussed with regard to FIGS. 13A to 13F. The MoO₂ film can grow on (001) Al₂O₃ substrate by pulsed laser deposition process. The KrF excimer laser (λ=248 nm, constant energy mode, Coherent) was used to ablate the MoO₂ target. The repetition rate of the ablation is 5 Hz. The PLD chamber standby vacuum was always keeping at about 10⁻⁹ Torr. O₂ atmosphere with pressure about 10⁻² torr was keeping in the chamber during the laser ablation process. Before the deposition, the pre-ablation process with 500 shots was carried out to clean the target. The Epi-MoO₂ film was grown on (001) Al₂O₃ substrate with a temperature of 400° C.

The ZnO film was grown on the (001) Al₂O₃ substrate by pulsed laser deposition process. The KrF excimer laser (λ=248 nm, constant energy mode, Coherent) was used to ablate the ZnO target. The repetition rate of the ablation is 1 Hz. The PLD chamber standby vacuum was kept at about 10⁻⁹ Torr. O₂ atmosphere with pressure about 5×10⁻² torr was kept in the chamber during the laser ablation process. Before the deposition, the pre-ablation process with 500 shots was carried out to clean the target. During the deposition process, the (001) Al₂O₃ substrate was kept at a temperature of 600° C.

The In₂O₃ film was grown on a (001) Al₂O₃ substrate by pulsed laser deposition process. The KrF excimer laser (λ=248 nm, constant energy mode, Coherent) was used to ablate the In₂O₃ target. The repetition rate of the ablation is 1 Hz. The PLD chamber standby vacuum was kept at about 10⁻⁹ Torr. O₂ atmosphere with a pressure of about 5×10⁻² torr was kept in the chamber during the laser ablation process. Before the deposition, the pre-ablation process with 500 shots was carried out to clean the target. During the deposition process, the (001) Al₂O₃ substrate was kept at a temperature of 500° C.

The carbonization of the MoO₂ film was carried out in the CVD system 200. The MoO₂ film was put inside the heating center in the quartz tube before the reaction started, the tube was pumped down to 20 mtorr and purged with Ar to eliminate the O₂ residue inside. For the whole reaction process, the 5 standard cubic centimeter per minute (sccm) CH₄ gas was provided as the carbon source and 100 sccm H₂ as the carrier and protection gas. The reaction pressure was kept at 10 torr. The time was 3 hrs for the rating from room temperature to the holding temperature of 800° C., then the holding time was also 3 hrs. Once the furnace was naturally cooled down to room temperature, the gas CH₄/H₂ flow was stopped and the Ar gas was used to purge the tube.

The nitridation was also carried out in the same CVD system, with a similar process as the carbonization process. However, the reaction atmosphere was a NH₃ gas with a flow rate of 200 sccm and pressure 10 torr. The rating time was also 3 hrs, and the holding temperature and time were 900° C. and 3 hrs.

The sulfurization process was carried out in a 3-zone CVD system as illustrated in FIG. 2. The sulfur flower powder in the ceramic crucible was put in the right zone and the MoO₂ film sample was put in the left zone. The Ar carrier gas flowed with 100 sccm from the right side to the left side, keeping the pressure inside the tube at about 6 torr. The holding temperature was 900° C., with a rating time of 45 mins and a holding time 1 hr. After the process was finalized, the system was naturally cooled down to RT.

The carbonization of the MoS₂ film is slightly modified from that of the MoO₂ film. Cu foil was utilized to cover the MoS₂ sample as a catalyst for the carbonization. In one application, the purchased Cu foil is sequentially cleaned by acetone/isopropanol/DI water to remove the organic residue. After this, it should be further cleaned by HCl aqueous solution to remove the surface oxide. The other reaction parameters were kept the same. The MoS₂ nitridation process is similar as the MoO₂ to MoN process.

The ZnS film was obtained through the sulfurization of ZnO in a three-zone CVD furnace, using the same equipment and sulfur vapor atmosphere as the MoS₂ growth process discussed above. However, the reaction holding temperature is 700° C. and the reaction time is about 8 hrs.

The In₂S₃ film was obtained through the sulfurization of a In₂O₃ layer in the three-zone CVD furnace, using the same equipment and sulfur vapor atmosphere as the MoS₂ growth process. However, the reaction holding temperature is 600° C. and the reaction time is about 60 hrs.

The transfer process of the large-scale MoS₂ film from the single crystal substrate to an amorphous substrate involved a purchased PDMS (Gel-Pak) film, which was attached on the surface of the MoS₂ film on the (001) Al₂O₃ substrate, making sure no air bubbles are present. Then, the sample with the PDMS film well-cohesive was merged in DI water for 4 hrs. After this, the PDMS film attached to the MoS₂ film was slowly detached from the Al₂O₃ substrate. After the detaching step, the PDMS/MoS₂ film was blow-dried and is attached to the target substrate, again making sure that no air bubbles are present. Then, the sample on the target substrate was put on the hotplate to heat at 70° C. for about 30 mins to reduce the bond between the PDMS film and the MoS₂ film. Finally, the PDMS film was detached, and the MoS₂ film remained attached to the amorphous substrate. The (001) Al₂O₃ substrate could be recycled thousands of times for growing and transferring the MoS₂ film, which could reduce the cost of the single crystalline substrates.

In one embodiment, a single-crystalline interlayer is developed on an amorphous substrate to enable a high-quality, single-crystalline, wide-band-gap semiconductor film. The single-crystalline layer can be grown on an amorphous quartz substrate, Molybdenum/Tungsten-alloy substrate or a silicon substrate. Therefore, a high-performance wide-bandgap semiconductor device (e.g., LED, high-electron mobility transistor (HEMT) or UV detector) could be fabricated on these non-lattice-matched substrates. Developing the single-crystalline nitride interlayer is based on the epitaxial phase heredity process discussed above together with a Van-der-Waal-layered film transfer process, also discussed above.

As illustrated in FIG. 13A, an epitaxial single-crystalline MoO₂ (can also be WO₂, NbO₂, VO₂) film 1302 (oxide layer) was generated on a single-crystal sapphire substrate 1304 through the pulsed laser deposition (or sputtering, metal-organic chemical vapor deposition (MOCVD), molecular beam epitaxy (MBE)). Then, through a high-temperature sulfurization step 1306, the single crystalline MoO₂ film 1302 is chemically converted, as shown in FIG. 13B, into a large-area (reach 6″ size, if using 6″ sapphire substrate) transferrable, single-crystalline layered MoS₂ film 1308 (or WS₂, NbS₂, VS₂ film). The film 1308 is referred to herein as a transferrable, single-crystal, chalcogenide film. The MoS₂ film 1308 can be peeled off in step 1310 by using a PDMS tape 1312 together with wet etching, as shown in FIG. 13C.

Then, the MoS₂ film 1308 on the PDMS tape 1312 could be transferred in step 1314 on an amorphous quartz substrate 1316 (or silicon substrate, or amorphous quartz, or Molybdenum/Tungsten alloy substrate) as shown in FIG. 13D. While this figure shows a transfer of the MoS₂ film 1308 with a tape, those skilled in the art would understand that any transfer method may be used, for example, an automatic method that is performed by a robot. Then, based on epitaxial heredity, through nitridation (or carbonization or other processes) process as discussed above, the MoS₂ film 1308 can be chemically converted in step 1318 into a single-crystalline hexagonal MoN (WN, NbN or VN or Mo₂C, W₂C, Nb₂C, V₂C) film 1320, as shown in FIG. 13E. This film is referred to herein as a single-crystal, non-oxide film.

Note that this large wafer-scale, single-crystalline, nitride interlayer film 1320 is directly grown on an amorphous substrate 1316. Since the interlayer MoN 1320 has a single-crystalline hexagonal structure, and the lattice mismatch between the MoN interlayer and the hexagonal GaN (or SiC, AIN, or GaₓIn_{y}Al_{z}N) is in an acceptable range, a high-quality, single-crystalline, GaN film 1324, with less dislocation defects density, can be successfully grown in step 1322 on the amorphous substrate 1316, through MOCVD or MBE growth methods, as shown in FIG. 13F. Thus, a high-performance, wide-bandgap semiconductor device (e.g., LED, HEMT and UV detectors) can be built directly on the amorphous substrate based on this process.

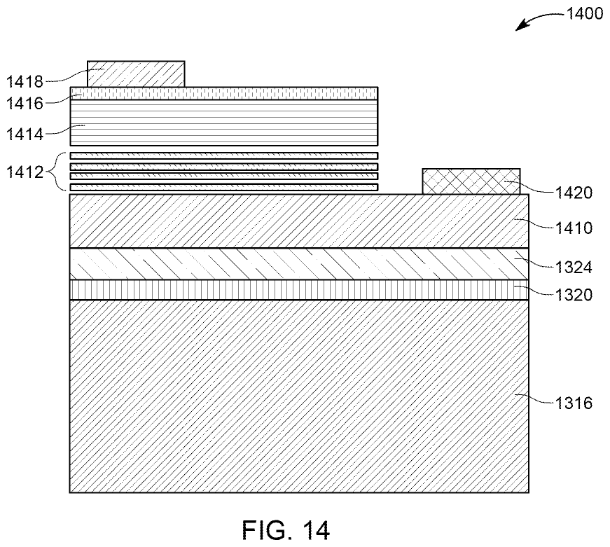

Such a device, e.g., a light emission diode 1400 (a representative application of the single-crystal MoN film on an amorphous substrate is to fabricate a wide-bandgap GaN LED device), is illustrated in FIG. 14 and includes the amorphous substrate 1316 and the single-crystal MoN film 1320 discussed in FIGS. 13A to 13F. The single-crystal MoN film 1320 is formed on the amorphous substrate 1316 as discussed in those figures. Then, the GaN buffer film 1324 from FIG. 13F is formed on top of the single-crystal MoN film 1320. Next, an N-type GaN film 1410 is formed over the GaN buffer film 1424, by known methods, for example, MBE system. InGaN/GaN mulitalyer quantum wells (MQWs) 1412 and P-type GaN film 1414 with Mg impurities are grown by MBE system, in this order, as illustrated in FIG. 14. An ITO transparent film 1416 is grown by sputtering over the P-type GaN film 1414. A P-type electrode 1418 and an N-type electrodes 1420 are grown by E-beam evaporation system on the ITO film 1416 and the N-type GaN film 1410, respectively, as shown in FIG. 14. The patterning of the ITO layer, P-type GaN: Mg film, InGaN/GaN multilayer quantum wells may be achieved by photo-lithography plus dry etching process. The patterning of the electrodes may be achieved by photo-lithography and liftoff process.

The device shown in FIG. 14 is just one possible implementation of the novel process described with regard to FIGS. 13A to 13F. Other implementations may include the single-crystalline hexagonal MoN, WN, NbN or VN or Mo2C, W2C, Nb2C, V2C film on an amorphous quartz substrate (or silicon substrate, Molybdenum/Tungsten alloy substrate) to grow the hexagonal GaN or SiC, AIN, or GaxInyAlzN wide-band-gap semiconductor films over a much larger area than the traditional methods. This process is advantageous for the Large-area displays. This technology also enables the wide-bandgap semiconductor-based LED, HEMT, UV-detector devices been fabricated with high-performances on cheap amorphous and metal-alloy substrates.

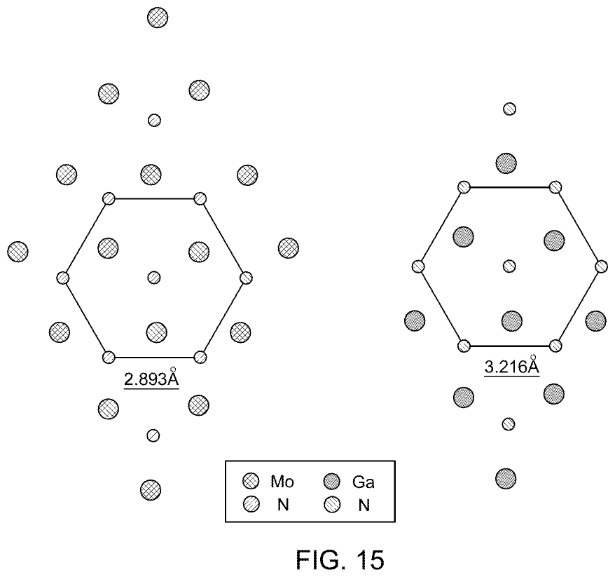

The devices noted above owe their high-performance due, in part, to the small lattice mismatch between (1) the single-crystal, non-oxide layers formed with the method of FIGS. 13A to 13F, and (2) the GaN films. In this regard, the single-crystalline MoN film on an amorphous substrate was confirmed to have a hexagonal structure. The lattice mismatch between the hexagonal GaN and the hexagonal MoN film is only 11%, see FIG. 15, which is much smaller than that between GaN and Al₂O₃ (mismatch: 33%). Thus, the high-quality, single-crystalline, GaN film could be successfully grown through MBE or MOCVD system on the amorphous substrate with the single-crystal, interlayer MoN film discussed herein. Those skilled in the art would understand that other layers may be grown on the interlayer MoN film shown in FIG. 14. In one embodiment, the interlayer MoN film may have a different chemical composition, for example, it can another single-crystal, non-oxide film that is grown with the methods illustrated in FIGS. 1, 2, and/or 13A to 13F. Further, instead of the LED device 1400, the process illustrated in FIGS. 13A to 13F may be used to form any opto-electronic device in which a single-crystal, non-oxide film needs to be formed (directly) over an amorphous substrate at large scale, e.g., at least 2 inch. The single-crystal, non-oxide film also experiences a chemical conversion to another single-crystal, non-oxide film, in which one chemical compound is (fully) replaced with another chemical compound.

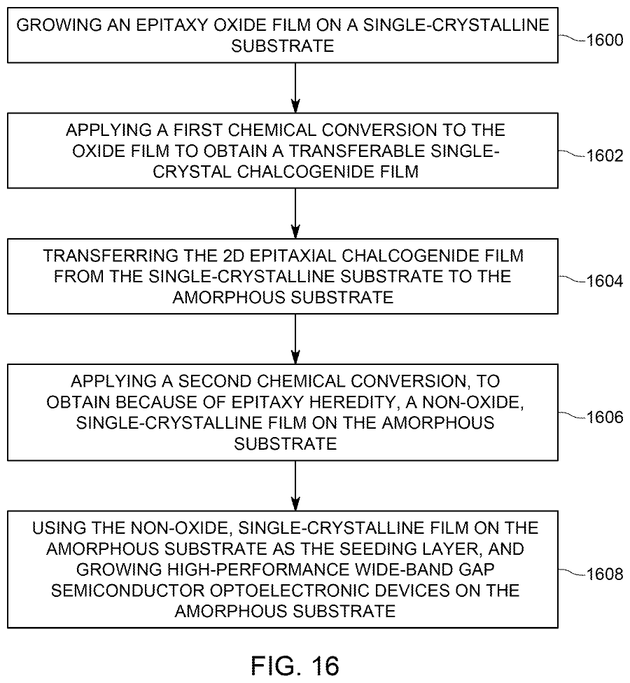

A method for making an opto-electronic device using the processes illustrated in FIGS. 13A to 13F is now discussed with regard to FIG. 16. The method includes a step 1600 of growing on a single-crystal substrate 1304 a single-crystal, oxide film 1302, a step of applying a first chemical processing 1602 to the single-crystal, oxide film 1302 to obtain a transferrable, single-crystal, chalcogenide film 1308, a step 1604 of transferring the single-crystal, chalcogenide film 1308 from the single-crystal substrate 1304 to an amorphous substrate 1316, a step 1606 of applying a second chemical processing to the single-crystal, chalcogenide film 1308 to obtain a single-crystal, non-oxide (nitride or carbide) film 1320, wherein the single-crystal, non-oxide film 1320 is different from the single-crystal, chalcogenide film 1308, and a step 1608 of growing wide-bandgap semiconductor films 1324 on the single-crystal, non-oxide film 1320 to obtain the opto-electronic device 1400. The first chemical processing is different from the second chemical processing.

The first chemical processing is usually sulfurization or selenylation, the second chemical processing is another one of the nitridation, or carbonization. The single-crystal oxide film is one of MoO₂, WO₂, NbO₂, and VO₂. The single-crystal, chalcogenide film is one of MoS₂, WS₂, NbS₂, and VS₂. The single-crystal, non-oxide layer is one of MoN, WN, NbN, and VN. In one application, the first chemical processing is sulfurization and the second chemical processing is nitridation. In another application, the single-crystal substrate is Al₂O₃ and the amorphous substrate is silicon with an amorphous capping layer, or amorphous quartz, or a metal.

The step of forming additional films may include forming a GaN buffer layer over the single-crystal, non-oxide film; forming an n-type GaN layer over the GaN buffer layer; forming a multi-quantum well layer over the N-type GaN layer; and forming a p-type GaN layer over the multi-quantum well layer.

The opto-electronic device is one of a light emitting diode, a photodetector, or a transistor. In one application, the processes illustrated in FIGS. 13A to 13F may be used to form an anode of a battery.

In another application, the method of making the opto-electronic device may include only the step 1604 of transferring a single-crystal, chalcogenide film 1308 from a single-crystal substrate 1304 to an amorphous substrate 1316, a step 1606 of applying a chemical processing to the single-crystal, chalcogenide film 1308 to obtain a single-crystal, non-oxide film 1320, where the single-crystal, non-oxide film 1320 is different from the single-crystal, chalcogenide film 1308, and a step 1608 of forming additional films 1324 on the single-crystal, non-oxide film 1320 to obtain the opto-electronic device 1400. The method may further includes a step 1600 of growing a single-crystal, oxide film 1302 on a single-crystal substrate 1304, and a step 1602 of applying another chemical processing to the single-crystal, oxide film 1302 to obtain the single-crystal, chalcogenide film 1308. Those skilled in the art would understand that the steps shown in FIG. 16 may be performed according to various sequences.

The disclosed embodiments provide an epitaxial heredity process to grow a single-crystal, chalcogenide film over a single-crystal substrate, to transfer the single-crystal, chalcogenide film over an amorphous substrate, and chemically transforms the single-crystal, chalcogenide film into a single-crystal, non-oxide film. It should be understood that this description is not intended to limit the invention. On the contrary, the exemplary embodiments are intended to cover alternatives, modifications and equivalents, which are included in the spirit and scope of the invention as defined by the appended claims. Further, in the detailed description of the exemplary embodiments, numerous specific details are set forth in order to provide a comprehensive understanding of the claimed invention. However, one skilled in the art would understand that various embodiments may be practiced without such specific details.

Although the features and elements of the present embodiments are described in the embodiments in particular combinations, each feature or element can be used alone without the other features and elements of the embodiments or in various combinations with or without other features and elements disclosed herein.

This written description uses examples of the subject matter disclosed to enable any person skilled in the art to practice the same, including making and using any devices or systems and performing any incorporated methods. The patentable scope of the subject matter is defined by the claims, and may include other examples that occur to those skilled in the art. Such other examples are intended to be within the scope of the claims.

1. A method for making a high-performance opto-electronic device on an amorphous substrate, the method comprising:
growing on a single-crystal substrate, a single-crystal, oxide film;
applying a first chemical processing to the single-crystal, oxide film to obtain a first transferrable, single-crystal, chalcogenide film;
transferring the transferrable, single crystal, chalcogenide film from the single-crystal substrate to an amorphous substrate or polycrystalline metal substrate;
applying a second chemical processing to the transferrable, single-crystal, chalcogenide film to obtain a single-crystal, non-oxide film), wherein the single-crystal, non-oxide film is different from the transferrable, single-crystal, chalcogenide film; and
growing a wide-bandgap semiconductor film using the single-crystal, non-oxide film as a seeding layer to obtain the opto-electronic device on the amorphous glass or polycrystalline metal substrate,
wherein the first chemical processing is different from the second chemical processing.

2. The method of claim 1, wherein the first chemical processing is one of sulfurization or selenylation, and the second chemical processing is one of nitridation or carbonization.

3. The method of claim 1, wherein the single-crystal, oxide film is one of MoO₂, WO₂, NbO₂, and VO₂.

4. The method of claim 1, wherein the transferrable, single-crystal, chalcogenide layer is one of MoS₂, WS₂, NbS₂, and VS₂.

5. The method of claim 1, wherein the single-crystal, non-oxide layer is one of MoN, WN, NbN, VN, and Mo₂C.

6. The method of claim 1, wherein the first chemical processing is sulfurization and the second chemical processing is nitridation.

7. The method of claim 1, wherein the single-crystal substrate is Al₂O₃ and the amorphous substrate is an amorphous quartz.

8. The method of claim 1, wherein the step of forming the wide-bandgap semiconductor film comprises:
forming a GaN buffer layer over the single-crystal, non-oxide film on the amorphous substrate or the polycrystalline metal substrate;
forming an n-type GaN layer over the GaN buffer layer;
forming a multi-quantum well layer over the N-type GaN layer; and
forming a p-type GaN layer over the multi-quantum well layer.

9. The method of claim 1, wherein the opto-electronic device is one of a light emitting diode, a photodetector, or a transistor.

10. An opto-electronic device comprising:
an amorphous substrate or a polycrystalline metal substrate;
a single-crystal, non-oxide film located directly on the amorphous substrate or the polycrystalline metal substrate;
a GaN buffer layer located directly over the single-crystal, non-oxide film;
an n-type GaN layer located directly over the GaN buffer layer;
a multi-quantum well layer located over the N-type GaN layer; and
a p-type GaN layer located over the multi-quantum well layer.

11. The device of claim 10, wherein the single-crystal, non-oxide film was obtained from a single-crystal, oxide film that was grown on a single-crystal substrate, the single-crystal, oxide film was transformed with a first chemical processing into an intermediary, transferrable, single-crystal, chalcogenide film, the intermediary, transferrable, single-crystal, chalcogenide film was transferred from the single-crystal substrate to the amorphous substrate or the polycrystalline metal substrate, and a second chemical processing was applied to the intermediary, transferrable, single-crystal, chalcogenide film to obtain the single-crystal, non-oxide film,
wherein the single-crystal, non-oxide film is different from the intermediary, transferrable, single crystal, chalcogenide film, and
wherein the first chemical processing is one of sulfurization or selenylation, and the second chemical processing is one of nitridation or carbonization.

12. The device of claim 10, wherein the single-crystal, oxide film is one of MoO₂, WO₂, NbO₂, and VO₂.

13. The device of claim 10, wherein the intermediary, transferrable, single-crystal, chalcogenide film is one of MoS₂, WS₂, NbS₂, and VS₂.

14. The device of claim 10, wherein the single-crystal, non-oxide film is one of MoN, WN, NbN, VN, and Mo₂C.

15. The device of claim 10, wherein the single-crystal substrate is Al₂O₃ and the amorphous substrate is an amorphous quartz.

16. The device of claim 10, wherein the opto-electronic device is one of a light emitting diode, a photodetector, or a transistor.

17. The device of claim 10, further comprising:
a transparent indium-tin-oxide (ITO) layer formed on the p-type GaN layer;
a first electrode formed directly on the ITO layer; and
a second electrode formed directly on the n-type GaN layer.

18. The device of claim 10, wherein a size of the single-crystal, non-oxide film is 10 cm by 10 cm or larger.

19. A method for forming an opto-electronic device, the method comprising:
transferring a transferrable, single-crystal, chalcogenide film from a single-crystal substrate to an amorphous substrate;
applying a chemical processing to the transferrable, single-crystal, chalcogenide film to obtain a single-crystal, non-oxide film, wherein the single-crystal, non-oxide film is different from the transferrable, single crystal, chalcogenide film; and
forming an additional film on the single-crystal, non-oxide film to obtain the opto-electronic device.

20. The method of claim 19, further comprising:
growing a single-crystal, oxide film on a single-crystal substrate; and
applying another chemical processing to the single-crystal, oxide film to obtain the transferrable, single-crystal, chalcogenide film.
